(19) United States
(12) Patent Application Publication
(10) Pub. No.: US 2010/0167491 A1
(43) Pub. Date: Jul. 1, 2010

(54) METHOD FOR FABRICATING FLASH MEMORY DEVICE

(76) Inventor: Min-Gon Lee, Eumseong-gun (KR)

Correspondence Address: SHERR & VAUGHN, PLLC, 620 HERNDON PARKWAY, SUITE 320, HERNDON, VA, 20170, US

(21) Appl. No.: 12/637,003

(22) Filed: Dec. 14, 2009

(30) Foreign Application Priority Data
Dec. 29, 2008 (KR) 10-2008-0135850

(51) Int. Cl. H01L 21/76; H01L 21/28

(52) U.S. Cl. 438/400; 438/587; 257/E21.54; 257/E21.209

(57) ABSTRACT

A method for fabricating a flash memory device includes forming device isolation films in a semiconductor substrate, defining active regions between the device isolation films, and patterning floating gates on the semiconductor substrate to correspond to the active regions. Portions where the active regions and the floating gates are not overlap with one another are within reference offset ranges, respectively.

The present application claims priority under 35 U.S.C. §119 to Patent Korean Application No. 10-2008-0135850 (filed on Dec. 29, 2008), which is hereby incorporated by reference in its entirety.

### BACKGROUND

The flash memory, being a non-volatile memory to which power is supplied continuously, allows contents to be erased therefrom in blocks or allows the programming of contents therein in blocks. Flash memory differs from EEPROM, which allows the erasure or revision of contents thereof at a byte level.

On the other hand, flash memory has a fast speed owing to revision in blocks. Flash memory is required to remove charge from a floating gate thereof for performing an erasing step. If residual charge remains at the floating gate in the erasing step, an erasing time increases. Meaning, as NOR flash cells become to have multi-levels, a erasing cell threshold voltage Vth serves an important role.

In a case the distribution of the threshold voltage Vth is too great to make proper erasure, a leakage current failure is caused. Therefore, if the distribution of the erasing cell threshold voltage Vth, the leakage current failure can be reduced.

FIG. 1 illustrates a section of a floating gate of a flash memory device. As illustrated in FIG. 1, device isolation films 110 in a semiconductor substrate define device isolation regions and active regions 120. Floating gates 130 are formed on and/or over the semiconductor substrate having the active regions 120 and the device isolation films 110 formed therein. Floating gate 130 is formed on and/or over the active region 120, and each of opposite edge portions of the floating gate 130 overlaps with a portion of the device isolation film. For example, if the device isolation film 110 has a width of K1, and the active region 120 has a width of K2, the floating gate 130 can have a width K3 greater than the width K2 of the active region 120. The overlap of the opposite edge portions of the floating gate 130 with the portions of the device isolation film 110 causes the column leakage.

### SUMMARY

Embodiments relate to semiconductor devices, and, more particularly, to a method for fabricating a flash memory device in which distribution of an erasing threshold voltage is enhanced for reducing a column leakage.

In accordance to embodiments, a method for fabricating a flash memory device can include at least the following: forming device isolation films in a semiconductor substrate, defining active regions between the device isolation films, patterning floating gates on and/or over the semiconductor substrate to correspond to the active regions such that portions where the active regions and the floating gates are formed do not overlap with one another and are within reference offset ranges, respectively. In this instance, the active regions and the floating gates can be patterned to match such that the active regions and the floating gates overlap with one another, entirely.

In accordance to embodiments, when the active region is defined to have a first area, the floating gate is patterned such that an area of the floating gate does not overlap with the active region is within the reference offset range. For an example, when the active region is defined to have a first area, the floating gate can be patterned to overlap with the active region, entirely.

In accordance to embodiments, when the floating gate is defined to have a second area, the device isolation films are patterned for forming the active regions each of which has an area not overlapped with the floating gate being within the reference offset range. For example, when the floating gate is defined to have a second area, the device isolation films are patterned for forming the active regions which overlap with the floating gates, entirely.

In accordance to embodiments, patterning the floating gate can include at least one of the following: forming polysilicon on and/or over the semiconductor substrate having the active regions each with the first area formed thereon and/or thereover, forming a first photoresist pattern on and/or over the polysilicon, and then etching the polysilicon by using the first photoresist pattern as a mask to pattern the floating gate.

In accordance to embodiments, defining the active regions can include defining the active regions each to have a first area between the device isolation films, patterning the floating gate can include patterning the floating gate on and/or over the semiconductor substrate such that the floating gate has a second area matched with the active region, and a portion where the active region defined to have the first area and the floating gate patterned to have the second area do not overlap is within the reference offset range. For an example, the active regions defined to have the first areas and the floating gates patterned to have the second areas are matched such that the active regions and the floating gates overlap with one another, entirely.

In accordance to embodiments, a method for fabricating a flash memory device can include at least the following: forming device isolation films in a semiconductor substrate and defining active regions between the device isolation films; and then patterning floating gates over the semiconductor substrate to correspond to the active regions such that portions where the active regions and the floating gates are not overlapped with one another are within reference offset ranges, respectively

In accordance to embodiments, a method for fabricating a flash memory device can include at least the following: forming device isolation films in a semiconductor substrate to define active regions in the semiconductor substrate located between the device isolation films; and then forming polysilicon over the semiconductor substrate; forming a first photoresist pattern over the polysilicon; and then forming floating gates over the semiconductor substrate corresponding to the active regions by etching the polysilicon using the first photoresist pattern as a mask such that the floating gates where the active regions and the floating gates are not overlapped with one another are within reference offset ranges, respectively.

### DRAWINGS

FIG. 1 illustrates a floating gate of a flash memory device.

Example FIGS. 2 to 7 illustrate a flash memory device and a method for fabricating a flash memory device, in accordance with embodiments.

### DESCRIPTION

Reference will now be made in detail to embodiments, examples of which are illustrated in the accompanying drawings. Wherever possible, the same reference numbers will be used throughout the drawings to refer to the same or like parts.

Example FIGS. 5A to 5C illustrate a method for fabricating a flash memory device in accordance with embodiments.

As illustrated in example FIG. 5A, device isolation films 515 are formed in the semiconductor substrate. For an example, the device isolation films 515 can be formed by shallow trench isolation (STI). Device isolation films 515 can be formed by coating photoresist on and/or over the semiconductor substrate, and subjected patterning the photoresist by photolithography to form a first photoresist pattern.

The semiconductor substrate is etched using the first photoresist pattern as a mask to form a plurality of trenches therein. An insulating material is then filled in the plurality of trenches to form the device isolation films 515. As the device isolation films 515 are formed, the semiconductor substrate between the device isolation films are defined as active regions 510.

The first photoresist pattern can be patterned such that each of the active regions 510 formed between the device isolation films 515 has a first width K2. If the active region 510 has a fixed length, the active region 510 can be defined to have a first area. For an example, the first photoresist pattern can be pattern such that an opening thereof has the first width K2.

As illustrated in example FIG. 5B, polysilicon 520 is formed on and/or over the semiconductor substrate having the active regions 510 each having the first area based on the first width K2 formed between the device isolation films 515. Then, a second photoresist pattern 525 is formed on and/or over the polysilicon 520 corresponding to the active regions 510, i.e., exposing the active regions 510. The second photoresist pattern 525 can have an opening with a second area based on the second width W1.

As illustrated in example FIG. 5C, the polysilicon 520 is etched using the second photoresist pattern 525 as a mask to form a floating gate 520-1 having a second area based on the second width W1. Then, the second photoresist pattern 525 is removed by ashing or stripping. By performing the patterning such that the floating gate 520-1 has the second area, a portion of the floating gate 520-1 not overlapping the active region 510 can become a reference offset range.

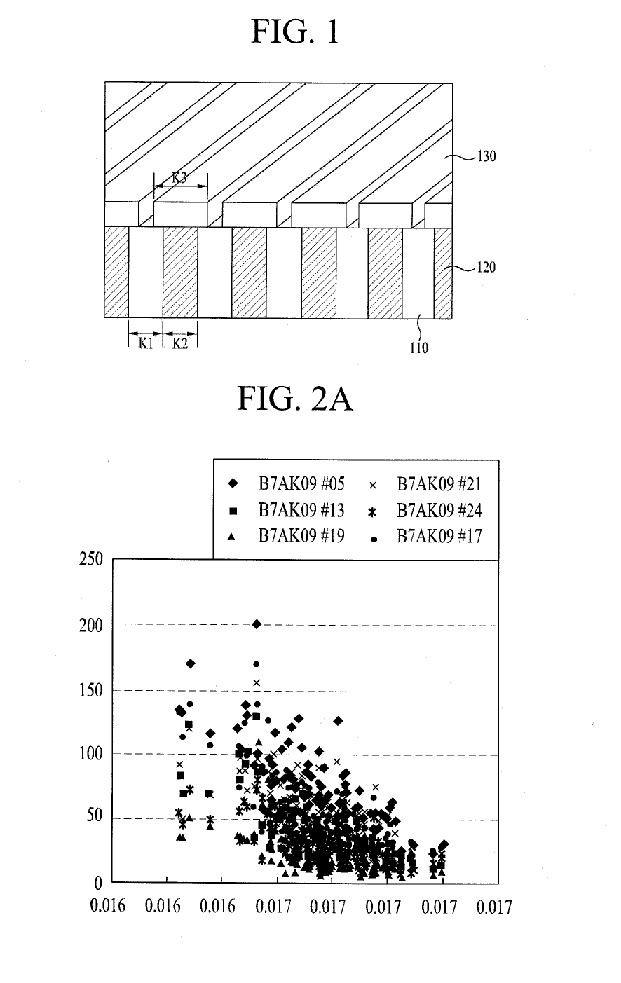

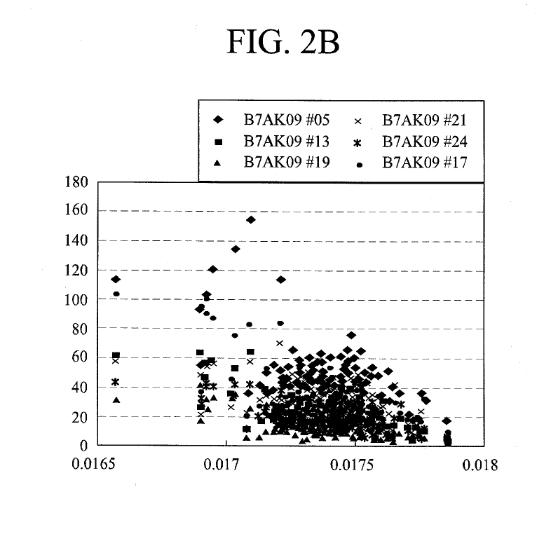

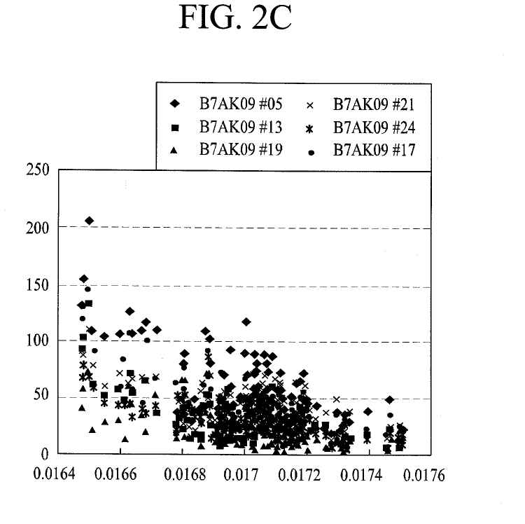

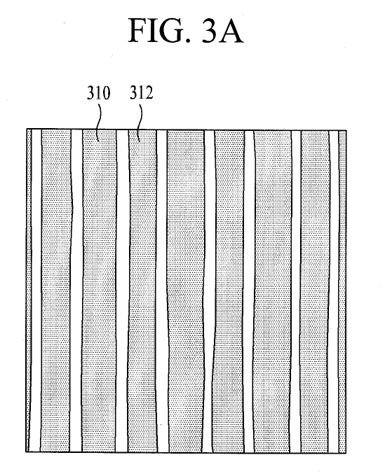

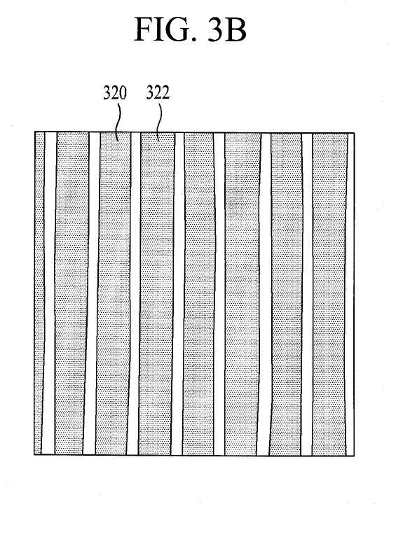

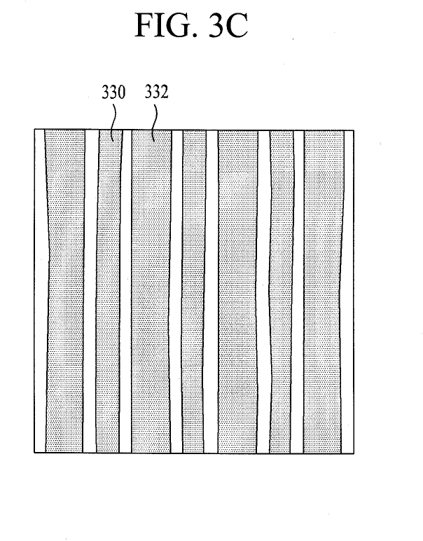

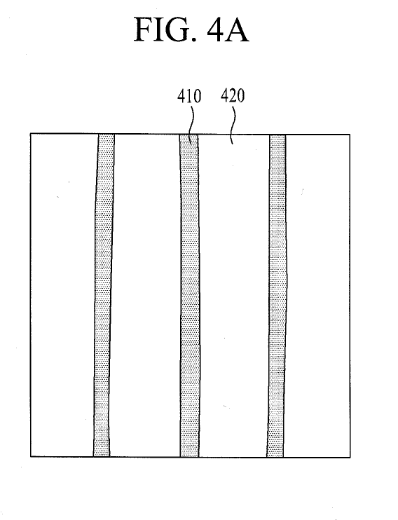

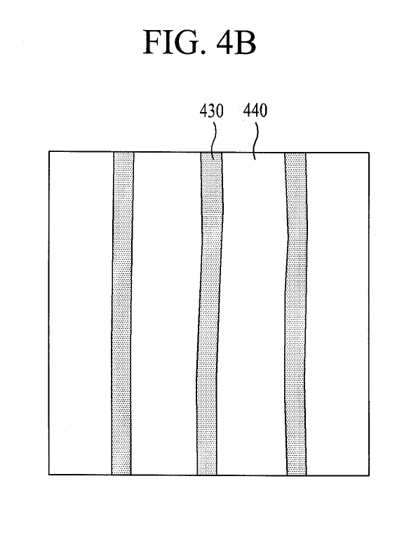

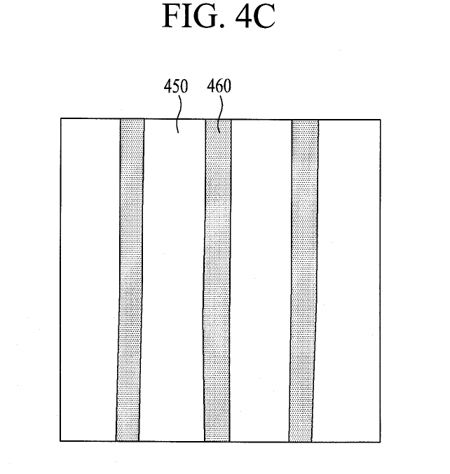

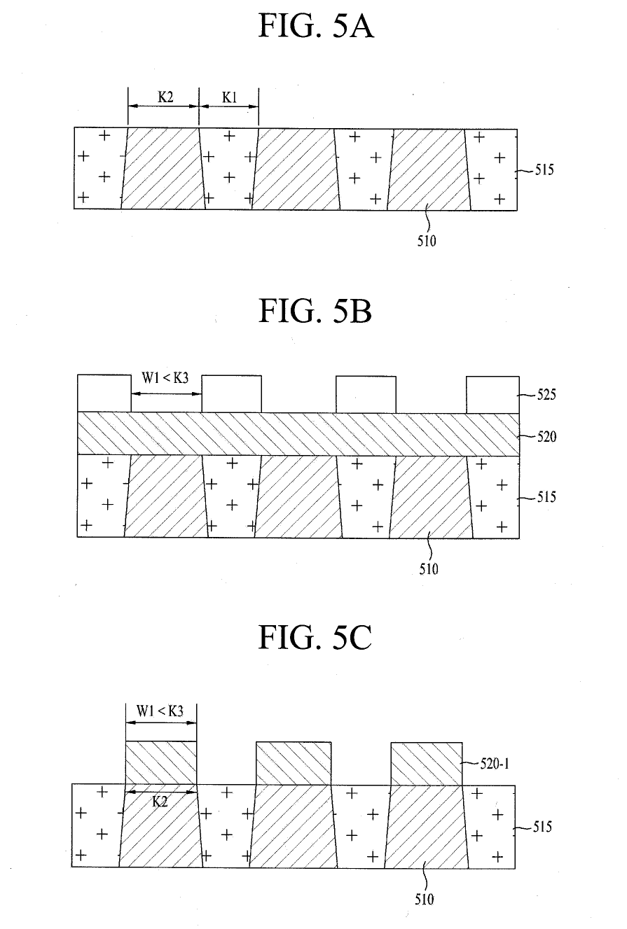

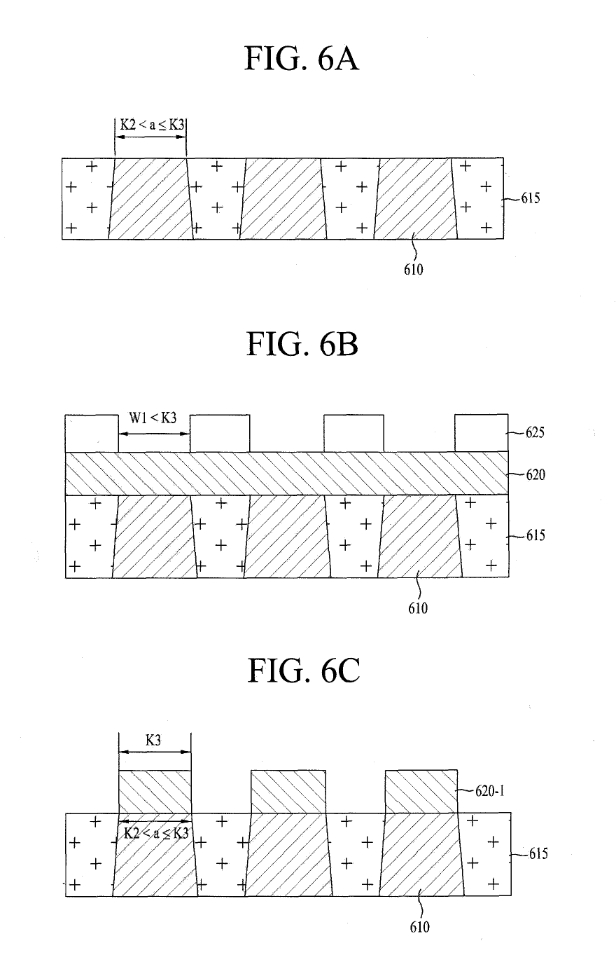

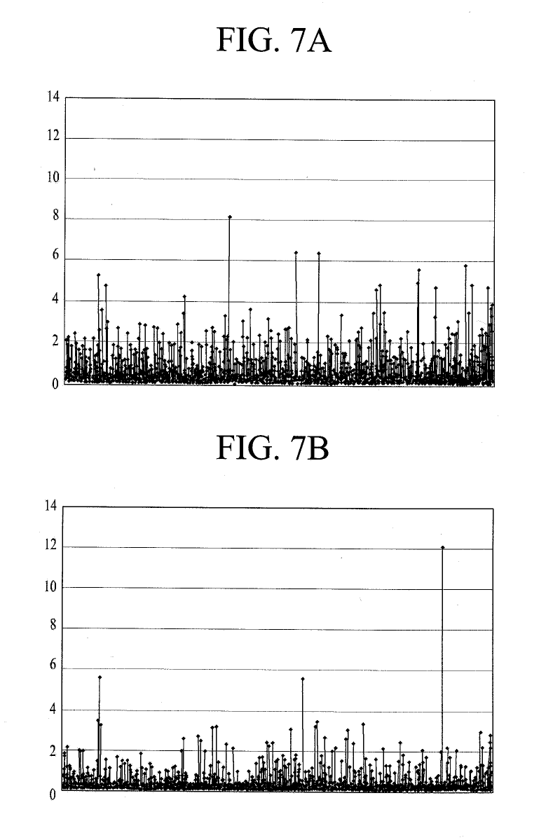

Though the area of the floating gate illustrated in FIG. 1 is greater than an area of the active region, to overlap with a portion of the device isolation film, in accordance with embodiments, the patterning is performed to reduce the width (or area) of the floating gate 520-1. For an example, by reducing the area of the opening of the second photoresist pattern 525, the width (or area) of the floating gate 520-1 can be reduced.

Example FIG. 5C illustrates the floating gates 520-1 and the active regions 510 matched, fully. In this instance, the width (or area) of the floating gate 520-1 is the same with the width (or area) of the active region 510.

Example FIGS. 2A to 2C illustrate graphs each showing an overlapped area of an active region and a floating gate vs. a leakage current. Example FIGS. 2A and 2C are related to opposite edge bit lines of the flash memory device, and example FIG. 2B is related to a middle bit line of the flash memory device. An X-axis represents an overlap area, and a Y-axis represents a column leakage. Those are graphs showing an intensity of the leakage current Y when one cell of 6 sheets of wafers (, ♦, ▪, ▴, x, *) in one lot named B7AK09 has an area X. It can be noted that the greater the area, the smaller the distribution of the leakage current Y.

As illustrated in example FIGS. 2A to 2C, it can be noted that the greater the overlapped area, the smaller the column leakage, and, when the floating gate area is fixed, the smaller the area of the active region, the greater the column leakage. Ideally, when the floating gate and the active region overlap completely, the leakage current will be the smallest.

Example FIGS. 3A to 3C illustrate active regions having critical dimensions CD changed. First CDs between the device isolation films 322 shown in example FIG. 3B are the CDs of the active region illustrated in FIG. 1B. Example FIG. 3A illustrates active regions 320 between the device isolation films 322 each having a −20 nm difference from the first CD, and example FIG. 3C illustrates active regions 320 between the device isolation films 322 each having a +20 nm difference from the first CD.

Example FIGS. 6A to 6C illustrate a method for fabricating a flash memory device in accordance with embodiments.

As illustrated in example FIG. 6A, device isolation films 615 are formed in a semiconductor substrate. For an example, photoresist can be coated on and/or over the semiconductor substrate, and subjected to patterning by photolithography to form a third photoresist pattern. The semiconductor substrate is etched using the third photoresist pattern as a mask to form a plurality of trenches therein. An insulating material is filled in the plurality of trenches to form linear device isolation films 615. The device isolation films 615 define the semiconductor substrate between the device isolation films 615 as active regions 610.

In this instance, the third photoresist pattern can be patterned such that each of the active regions 610 between the device isolation films 615 has a third area when lengths of the active regions 610 are fixed. For an example, the third photoresist pattern can be formed such that openings thereof have third areas, respectively. When lengths of the active regions 610 are fixed, the third area can be fixed by a third width a. The third width a can be greater than the width K2 of the active region illustrated in FIG. 1, and smaller than or equal to a width K3 of the floating gate 620-1 to be formed later. The width (or area) of the floating gate 620-1 to be formed later can be the same with the width (or area) of the floating gate 130 in FIG. 1. After formation of the device isolation films 615, the third photoresist pattern is removed.

As illustrated in example FIG. 6B, polysilicon 620 is formed on and/or over the semiconductor substrate having the active regions each having the third area defined therein. Then, photolithography is performed to form a fourth photoresist pattern 625 on and/or over the polysilicon 620.

As illustrated in example FIG. 6C, the polysilicon 620 is etched using the fourth photoresist pattern 625 as an etch mask to form a floating gate 620-1. In this instance, an area of the floating gate 620-1 can be predetermined. Therefore, the active regions 610 can be patterned such that portions where the floating gate 620-1 having the predetermined areas and the active regions 610 patterned to have the third widths not overlap with one another are within a reference offset range.

The method for fabricating a flash memory device illustrated in example FIGS. 6A to 6C can reduce the column leakage by changing, not the width of the floating gate, but the width of the active region to increase the area where the floating gate and the active region overlap with one another.

Example FIGS. 4A to 4C illustrate floating gates having changed critical dimensions CD. Second CDs on spaces between the floating gates 440 illustrated in example FIG. 4B are a case of the device illustrated in FIG. 1B. The CDs on spaces between the floating gates 420 in example FIG. 4A are CDs each having a −20 nm difference from the second CD. The CDs on spaces between the floating gates 450 in example FIG. 4C are CDs each having a +20 nm difference from the second CD.

By changing the CD on the spaces between the floating gates at the time of floating gate patterning, an overlap area between the floating gate and the active region can be increased.

Example FIG. 7A illustrates distribution of erasing threshold voltages of cells formed at an active region having a related art critical dimension CD. Example FIG. 7B illustrates distribution of erasing threshold voltages of cells formed at an active region in accordance with embodiments. An X-axis represents a cell distribution and a Y-axis represents a cell threshold voltage.

As illustrated in example FIGS. 7A and 7B, it is required to reduce the distribution of the erasing threshold voltage for reducing the column leakage. It can be known that the distribution of the erasing threshold voltage is reduced when the CD of the active region is increased, and spaces between the floating gates are increased. Accordingly, the column leakage can be reduced.

As has been described, the method for fabricating a flash memory device in accordance with embodiments has the following advantages. By increasing critical dimensions on the active regions and changing the critical dimensions on the spaces between floating gates at the time of patterning the floating gates, an overlapped area between the floating gate and the active region is increased, thereby enhancing a distribution of the erasing threshold voltage, which in turn reduces the column leakage.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method comprising:
forming device isolation films in a semiconductor substrate and defining active regions between the device isolation films; and then
patterning floating gates over the semiconductor substrate to correspond to the active regions,
wherein portions where the active regions and the floating gates are not overlapped with one another are within reference offset ranges, respectively.

2. The method of claim 1, wherein each floating gate is patterned to overlap only with the active region.

3. The method of claim 1, wherein the active region is defined to have a first area and the floating gates are patterned such that an area of each floating gate not overlapping with the active region is within the reference offset range.

4. The method of claim 3, wherein when the active region is defined to have the first area, each floating gate is patterned to overlap only with the active region.

5. The method of claim 1, wherein the floating gate is defined to have a second area and the device isolation films are formed such that the active regions each have an area not overlapped with the floating gate being within the reference offset range.

6. The method of claim 5, wherein when each floating gate is defined to have a second area, the device isolation films are formed such that the active regions overlap entirely with the floating gates.

7. The method of claim 3, wherein patterning the floating gates comprises:
forming polysilicon over the semiconductor substrate having the active regions each with the first area;
forming a first photoresist pattern over the polysilicon; and then
etching the polysilicon using the first photoresist pattern as a mask to pattern the floating gate.

8. The method of claim 1, wherein defining the active regions comprises:
defining the active regions each to have a first area between the device isolation films.

9. The method of claim 8, wherein patterning the floating gate comprises:
patterning the floating gates over the semiconductor substrate such that each floating gate has a second area corresponding to a respective active region.

10. The method of claim 9, wherein a portion where the active region defined to have the first area and the floating gate patterned to have the second area do not overlap is within the reference offset range.

11. The method of claim 10, wherein the active regions defined to have the first areas and the floating gates patterned to have the second areas are matched such that the active regions and the floating gates entirely overlap with one another.

12. A method comprising:
forming device isolation films in a semiconductor substrate to define active regions in the semiconductor substrate located between the device isolation films; and then
forming polysilicon over the semiconductor substrate;
forming a first photoresist pattern over the polysilicon; and then
forming floating gates over the semiconductor substrate corresponding to the active regions by etching the polysilicon using the first photoresist pattern as a mask,
wherein the floating gates where the active regions and the floating gates are not overlapped with one another are within reference offset ranges, respectively.

13. The method of claim 12, wherein defining the active regions comprises:
defining the active regions each to have a first area between the device isolation films.

14. The method of claim 12, wherein the active region is defined to have a first area and the floating gates are patterned such that an area of each floating gate not overlapping with the active region is within the reference offset range.

15. A method comprising:
forming device isolation films in a semiconductor substrate and defining active regions between the device isolation films to have a first area; and then
patterning floating gates over the semiconductor substrate to correspond to the active regions,
wherein portions where the active regions and the floating gates are not overlapped with one another are within reference offset ranges, respectively.

16. The method of claim 15, wherein patterning the floating gates comprises:
forming polysilicon over the semiconductor substrate having the active regions;
forming a first photoresist pattern over the polysilicon; and then
etching the polysilicon using the first photoresist pattern as a mask.

17. The method of claim 15, wherein the floating gates are patterned such that an area of each floating gate not overlapping with the active region is within the reference offset range.

18. The method of claim 15, wherein patterning the floating gate comprises:
patterning the floating gates over the semiconductor substrate such that each floating gate has a second area corresponding to a respective active region.

19. The method of claim 15, wherein a portion where the active region defined to have the first area and the floating gate patterned to have the second area do not overlap is within the reference offset range.

20. The method of claim 1, wherein the floating gate is defined to have a second area and the device isolation films are formed such that the active regions each have an area not overlapped with the floating gate being within the reference offset range.
